(19) United States
(12) Patent Application Publication
(10) Pub. No.: US 2005/0158580 A1
(43) Pub. Date: Jul. 21, 2005

(54) Organic electro luminescent display device

(76) Inventors: Masato Ito, Mobara (JP); Naoyuki Ito, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 10/997,928

(22) Filed: Nov. 29, 2004

(30) Foreign Application Priority Data
Nov. 28, 2003 (JP) 2003-399381

(51) Int. Cl. H05B 33/12

(52) U.S. Cl. 428/690; 428/917; 313/504; 313/506

(57) ABSTRACT

An object of the invention contained in the present application is to maintain a light emission efficiency and attain a long service life by suppressing a temperature rise in an organic multilayer film to be caused by light emission. The present application contains a plurality of features capable of attaining this object. One of these features is a method for producing an organic EL display device containing a first step of forming an organic light emitting layer on an anode formed on a major face of a glass substrate and, then, forming a cathode in a film state on the thus-formed organic light emitting layer, a second step of forming a phase transfer material layer which performs phase transfer in the range of from room temperature to about 100° C. on the thus-formed cathode and, then, sealing a major face side, namely, an organic EL light emitting element side of a substrate by a sealing container; and a third step of housing a desiccant on an inner face of the sealing container and, then, performing such sealing by bonding the sealing container to the glass substrate by using a sealing agent.

### CROSS-REFERENCE TO RELATED APPLICATIONS

The disclosure of Japanese Patent Application No. P2003-399381 filed on Nov. 28, 2003 including the specification, drawings and abstract is incorporated herein by reference in its entirety.

### BACKGROUND

1. Field of the Invention

The present invention relates to organic electro luminescent display devices and, particularly, to an organic electro luminescent display device capable of realizing a long service life and enhancing reliability by suppressing deterioration of efficiency in a light emitting region to be caused by heat generated in an organic layer constituting the light emitting region.

2. Description of Related Arts

A liquid crystal display deice (LCD), a plasma display device (PDP), an electric field emission-type display device (FED), an organic electro luminescent (EL) display device (OLED) and the like are in practical use or under studies as a flat panel-type display device. Among these devices, the organic EL display device is extremely promising as a typical thin light-weight self-luminous-type display device in the future. There are, what is called, a bottom emission-type and a top emission-type in the organic EL display device. In the bottom emission-type organic EL display device, an organic EL element is constituted by a light emission mechanism in which a transparent electrode (for example, ITO) as a first electrode or one of electrodes, an organic multilayer film (hereinafter referred to also as “organic light emitting layer”) which emits light by being applied with an electric field and a reflective metallic electrode as a second electrode or the other electrode are sequentially laminated on an insulating substrate which is favorably a glass substrate. A multiple of such organic EL elements are arranged in a matrix state and, then, another substrate denoted as a sealing container is provided such that the container covers the resultant laminated constitution, to thereby block the light emitting constitution from an outside atmosphere. Thereafter, carriers (electron and hole) are injected into the organic multilayer film by applying the electric field between, for example, the transparent electrode which is defined as an anode and the metallic electrode which is defined as a cathode and, then, the organic multilayer film emits light. It is constituted that such light emission is ejected outside from the side of the glass substrate.

On the other hand, the organic EL display device of the top emission type is characterized by a constitution in which the aforementioned one of electrodes is defined as the metallic electrode having a reflective property and the other electrode is defined as the transparent electrode such as ITO and, then, the organic multilayer film emits light by applying the electric field between these electrodes and, thereafter, the thus-emitted light is ejected from the side of the aforementioned other electrode. In the top emission type, a transparent sheet which is favorably a glass sheet is used as the sealing container of the bottom emission type.

In such an organic EL display device as described above, at the time of light emission of the organic EL element, the carriers are injected in the multilayer film of the light emission mechanism in accordance with the electric filed to be applied between the one of electrodes and the other electrode and, then, light is emitted; however, thus-injected carriers do not all contribute to light emission and a part thereof is changed into heat to raise a temperature of the light emission mechanism. Materials of an organic EL multilayer film constituting the light emission mechanism are ordinarily deteriorated in a light emitting property by heat, to thereby shorten a service life. For this account, it is necessary to remove generated heat. As articles in which measures against such heat generation have been taken, an article in which a material of the organic EL multilayer film has been improved in thermal resistance is described in Patent Document 1, further, another article in which a heat radiating fin is provided is described in Patent Document 2 and, still further, another article in which a coolant is filled in a sealing container is described in Patent Document 3 as follows:
Patent Document 1: JP-A No. 10-233283;
Patent Document 2: JP-A No. 2003-22891; and
Patent Document 3: JP-A No. 2002-93575.

### SUMMARY

As has been described above, an organic multilayer film constituting a light emission mechanism of an organic EL display device is deteriorated in a light emitting property by heat generation. Further, the heat generation is also a factor of inhibiting realization of a long service life of an organic EL display device. Therefore, an object of the invention is to provide an organic EL display device which maintains light emission efficiency and attains a long service life by suppressing a temperature rise of an organic multilayer film to be caused by light emission.

According to the invention, in order to achieve the aforementioned object, a plurality of features are provided. Four representative features there among are described below.

As a first feature according to the invention, provided is a constitution in which, after the other electrode of an organic EL element is formed, a material layer which performs phase transfer in the temperature range of from room temperature (approximately from 20° C. to 25° C.) to approximately 100° C. is formed on the thus-formed electrode or filled therein and, then, the resultant article is sealed in a sealing container, to thereby absorb heat generated in an organic EL material as a phase transfer energy.

Further, as a second feature according to the invention, provided is a constitution in which, after an organic EL element is formed, a gas barrier film such as a polymer, a silicon nitride film or a silicon oxide film is formed such that it covers the organic EL element and, then, a material layer which performs phase transfer in the aforementioned temperature range is formed on the thus-formed gas barrier film, to thereby absorb heat generated in an organic EL material as a phase transfer energy.

Still further, as a third feature according to the invention, provided is a constitution in which graphite, a metallic grain or the like is mixed into a material which performs phase transfer of the aforementioned first or second feature, to thereby enhance a thermal conductive effect.

Furthermore, as a fourth feature according to the invention, provided is a constitution in which a film having a high thermal conductivity such as a metallic film is formed on the material which performs the phase transfer in any one of the first to fourth features, to thereby facilitate a more effective heat removal.

By these features according to the invention, the heat generated by the carriers which do not contribute to light emission is absorbed by the material layer which performs the phase transfer (hereinafter, referred to also as “phase transfer material layer”) as the phase transfer energy of the phase transfer material layer. By mixing graphite or the metallic grain into the phase transfer material layer, the heat generated in the organic EL multilayer film can efficiently be quickly transferred as the phase transfer energy of the phase transfer material layer. Further, by forming the film having the high thermal conductivity such as the metallic film on the phase transfer material layer, the thermal energy transferred into the phase transfer material layer is efficiently discharged outside from the side of the sealing container. By each of the aforementioned features according to the invention, it does not occur that the heat generated in the organic multilayer film heats the organic multilayer film and deteriorate the light emission efficiency. As a result, a long service life can be attained.

Further, although a substrate constitution of the organic EL display device of the bottom emission type has been described, the same holds true for the organic EL display device of the top emission type according to the invention. In a case of the organic EL display device of the top emission type, it is permissible so long as, firstly, the aforementioned phase transfer material layer is provided on a glass substrate and, then, one of electrodes is formed in a film state on the thus-provided layer and, thereafter, an organic multilayer film and the other electrode are formed on the thus-provided electrode in the stated order. Further, in a case of using the film having the high thermal conductivity such as the metallic film constituting the aforementioned fourth feature according to the invention, it is permissible so long as the metallic film or the like is formed before the phase transfer material layer is formed on the glass substrate.

Still further, the phase transfer material layer is not limited to being formed on a reverse side of the organic light emitting layer of the one of electrodes or the other electrode and can be formed between the one of electrodes or the other electrode and the organic light emitting layer. In this case, a protective layer is optionally formed therebetween for the purpose of preventing a detrimental influence from being exerted on the light emission function of the organic light emitting layer.

Furthermore, a heat radiation efficiency can be enhanced by allowing an end portion of the phase transfer material layer in each of such constitutions as described above to be in direct contact with a metallic wiring such as a reference potential line or an optionally provided metallic film formed on the glass substrate, or the glass substrate.

### BRIEF DESCRIPTION OF THE DRAWINGS

FIG. 1 is a cross-sectional diagram schematically showing a layer constitution of an organic EL element of Example 1 of an organic EL display device according to the invention;

FIG. 2 is a cross-sectional diagram schematically showing an entire constitution of Example 1 of an organic EL display device according to the invention;

FIG. 3 is a cross-sectional diagram schematically showing a layer constitution of an organic EL element of Example 2 of an organic EL display device according to the invention;

FIG. 4 is a cross-sectional diagram schematically showing a layer constitution of an organic EL element of Example 3 of an organic EL display device according to the invention;

FIG. 5 is a cross-sectional diagram schematically showing a layer constitution of an organic EL element of Example 4 of an organic EL display device according to the invention;

FIG. 6 is a cross-sectional diagram showing an example of constitution of a neighborhood of an organic EL element, namely, one pixel of an organic EL display device of a bottom emission type to which the invention is applied; and

FIG. 7 is an equivalent circuit diagram showing an example of an entire constitution of an organic EL display device of an active matrix type according to the invention.

### DETAILED DESCRIPTION OF THE INVENTION

Hereinafter, embodiments according to the invention will be described in detail with reference to drawings. On this occasion, an organic EL display device of a bottom emission type is described.

### EXAMPLE 1

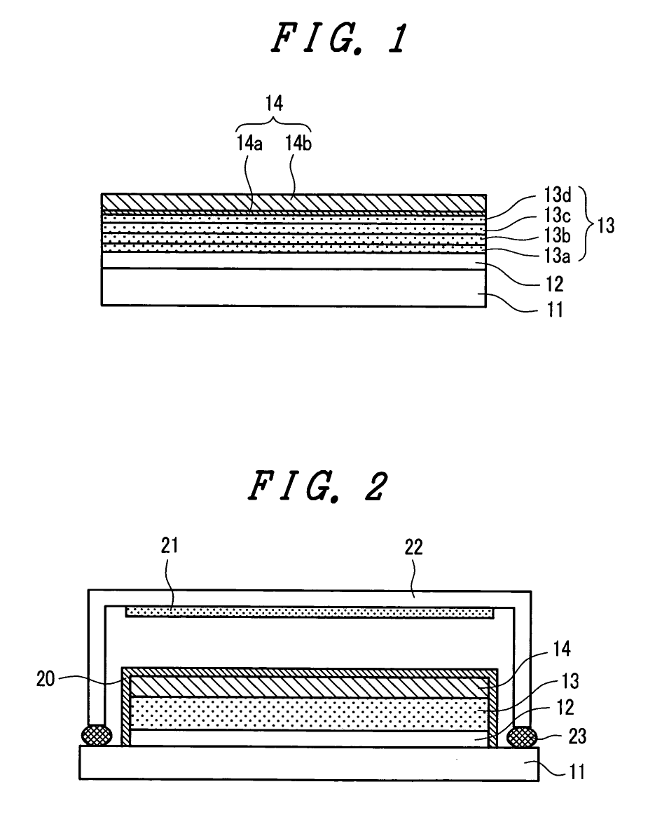

FIG. 1 is a cross-sectional diagram schematically showing a layer constitution of an organic EL element of Example 1 of an organic EL display device according to the invention. Further, FIG. 2 is a cross-sectional diagram schematically showing an entire constitution of Example 1 of an organic EL display device according to the invention. The organic EL element constituting the organic EL display device comprises, as shown in FIG. 1, an anode 12 which is one of electrodes formed on a major face (inner face) of a glass substrate 11. In the anode 12, a transparent conductive film of, for example, ITO (indium/tin/oxide: In-Tin-O) or IZO (indium/zinc/oxide:. In—Zn—O) can be used and, on this occasion, it is defined as ITO. Further, although not shown, in an active matrix type, a pixel selective circuit (or pixel driver circuit) comprising a thin film transistor (TFT) formed by, for example, LTPS (low-temperature polysilicon semiconductor film) is formed on the major face of the glass substrate 11.

An organic multilayer film 13 constituting an organic light emitting constitution of an organic EL element is formed on the anode 12 which is also denoted as a lower electrode. Such organic multilayer film 13 is formed by laminating a hole injecting layer 13a, a hole transport layer 13b, a light emitting layer 13c and an electron transport layer 13d in the stated order from the side of the anode 12. Then, a cathode 14 as the other electrode is formed in a film state as an uppermost layer. Thickness of the organic multilayer film 13 is, for example, 150 nm. The cathode 14 is constituted by lithium fluoride (LiF) 14a as a first layer on the side of the electron transport layer 13d and an aluminum (Al) layer 14b as a second layer formed thereon. Thickness of lithium fluoride 14a as a film is, for example, 1 nm, while thickness of the aluminum layer 14b is, for example, 200 nm.

An example of each material of the organic multilayer film 13 is described below. Namely, the hole injecting layer 13a comprises CuPc (copper phthalocyanine) or the like; the hole transport layer 13b comprises α-NPD (α-naphthyl phenyl diamine) or the like; the light emitting layer 13c comprises light emitting materials comprising 9,10-diphenyl anthracene or the like as a host material and perylene or the like as a dopant material; and the electron transport layer 13d comprises Alq 3 (tris(8-hydroxyquinoline) aluminum) or the like.

Then, as shown in FIG. 2, a material layer, namely, a phase transfer material layer 20, which performs a phase transfer in the range of from approximately room temperature to approximately 100° C. is formed on an upper face of the cathode 14 and on the side faces of the anode 12, the organic multilayer film 13 and the cathode 14. The phase transfer material layer 20 is formed such that it covers an entire display region in which organic EL elements are two-dimensionally arranged and, in a strict sense of meaning, formed such that it is also in contact with the glass substrate 11. Even in a case in which the phase transfer material layer 20 is not formed on the side faces of the anode 12, the organic multilayer film 13 and the cathode 14, a sufficient effect can be expected so long as it exists on the cathode 14; however, in order to secure a higher heat radiation property, it is preferable that it also exists on the sides thereof. Nevertheless, in a case in which it is formed directly on these sides without interposing a barrier layer or the like, it is necessary to constitute the phase transfer material layer 20 by a non-conductive material in order to prevent the anode 12 and the cathode 14 from forming a short-circuit therebetween or from losing functions thereof. The major face of the substrate of the resultant organic EL light-emitting element thus constituted is sealed by a sealing container 22. A desiccant 21 is housed in an inner face of the sealing container 22 and, then, sealing is performed by bonding it to the glass substrate 11 by using a sealing agent 23. The desiccant 21 which is prepared by allowing an ordinary desiccant to be in sheet form is attached to the inner face of the sealing container 22 or the desiccant 21 in gel form is applied thereto. Further, as for the sealing agent 23, an ultraviolet curing-type resin is used; however, other types of resins may be used as the sealing agent 23.

As for the materials for the phase transfer material layer 20, liquid crystalline polymers represented by the following chemical formulae (1) to (6) are mentions: 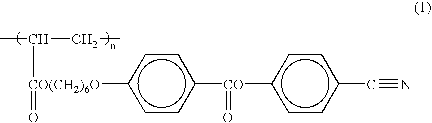
poly(6-{4-[(4-cyanophenoxy)carbonyl]phenoxy}hexylacrylate); 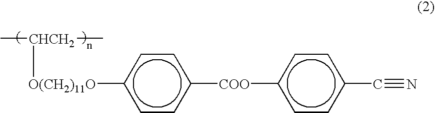
poly(1-{11-[4-(4-cyanophenoxycarbonyl)phenoxy]undecyloxy}ethylene); 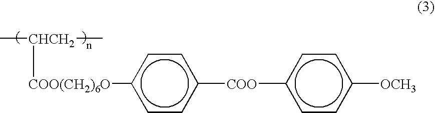
poly(1-{6-[4-(4-methoxyphenoxycarbonyl)phenoxy]hexyloxycarbonyl}ethylene); 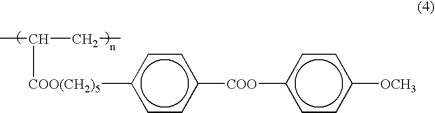
poly(1-{5-[4-(4-methoxyphenyloxycarbonyl)phenyloxy]pentyloxycarbonyl}ethylene); 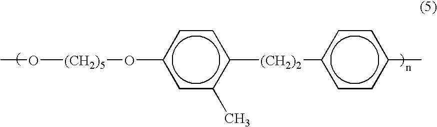
poly[oxypentane-1,5-diyloxy(3-methyl-1,4-phenylene)ethylene-1,4-phenylene]; and 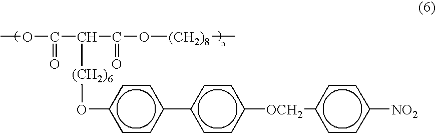
poly(oxy-2-{6-[4′-(4-nitrophenyl)methyloxybiphenyl-4-yl]oxyhexyl}malonyloxyoctane-1,8-diyl).

Further, the aforementioned materials can be used either singly or in mixtures of two types or more thereof.

Still further, as for materials for the phase transfer material layer 20, following polymeric compounds, for example, are mentioned:
poly(methyl vinyl ether);
methyl cellulose;
poly(ethylene oxide);
poly(vinyl oxazolidinone);
poly(N-isopropyl acrylamide);
derivatives of polyacrylamide; and
a copolymer of N-vinyl formamide.

These materials may be used singly, in mixtures of two types or more thereof, in a composition in which any one of these materials is further added with a solvent such as water or in a gelated article in which any one of them is further added with a cross-linking agent.

Furthermore, as for materials for the phase transfer material layer 20, following polymeric compounds, for example, each having a low glass transition temperature, namely, the organic EL materials each having a heat generation range of from about 20° C. to about 50° C. and block copolymers thereof are mentioned; these materials can be used either singly or in mixtures of two types or more thereof:
poly(2-methyl-1-pentene);
poly(1,1,2-trimethylpropane-1,3-diyl);
poly(bicyclo[2,2,1]hept-2-ene);
poly(4-ethylstyrene);
poly(4-octadecylstyrene);
polystyrene;
poly(5-bromo-2-isopropoxystyrene); and
poly(9-vinylcarbazole).

Further, by allowing the phase transfer material layer to be in contact with a metallic portion of wiring or the like such as a reference potential line on the glass substrate 11, the organic EL display device can be constituted such that heat absorbed by the phase transfer material layer is discharged outside from the substrate 11. According to the organic EL display device having such a constitution as shown in Example 1, the heat, generated by the carriers, which does not contribute to the light emission in the light emitting layer is absorbed by the phase transfer material layer as the phase transfer energy of the phase transfer material layer and, then, deterioration of the light emission efficiency is suppressed and, accordingly, a long service life of the organic EL display device can be attained.

### EXAMPLE 2

FIG. 3 is a cross-sectional diagram schematically showing a layer constitution of an organic EL element of Example 2 of an organic EL display device according to the invention. Further, explanations of same components as those in Example 1 are omitted. In Example 2, in a same manner as in Example 1, one of electrodes (anode) 12, an organic multilayer film 13 constituting an organic light emission constitution of the organic EL element, a cathode 14 which is the other electrode are formed on a glass substrate 11. According to the present embodiment, a gas barrier film 30 is provided as an upper layer of the cathode 14. As for the gas barrier film 30, a polymer film of, for example, poly(vinylidene chloride) (hereinafter, referred to also as “PVDC” in short), a vapor-deposited film of, for example, poly(para-xylene), and a gas non-permeable material layer of, for example, a silicon nitride film or a silicon oxide film are mentioned. Then, a phase transfer material layer 20 comprising same material as in Example 1 is formed on the thus-formed gas barrier layer 20. Further, an entire constitution in which a sealing container is provided is similar to that in FIG. 2. A constitution of heat radiation from the phase transfer material layer is same as in Example 1.

According to the organic EL display device constituted as in Example 2, in addition to the effect in Example 1, there is no influence to the organic light emitting layer by a gas such as moisture which is possible to be generated with a temperature rise of the phase transfer material layer and, accordingly, a long service life can be attained.

### EXAMPLE 3

FIG. 4 is a cross-sectional diagram schematically showing a layer constitution of an organic EL element of Example 3 of an organic EL display device according to the invention. Further, explanations of same components as those in Examples 1 and 2 are omitted. In Example 3, after a same gas barrier film 30 as in Example 2 is provided, a phase transfer material layer 40 in which a material having a high thermal conductivity is dispersed is further formed on the thus-provided gas barrier film 30. As for the material having the high thermal conductivity which is dispersed in the phase transfer material layer 40, graphite or a metallic grain can be mentioned.

According to the organic EL display device constituted as in Example 3, in addition to the effects in Examples 1 and 2, the material having the high thermal conductivity which is dispersed in the phase transfer material layer 40 promotes, not only incorporation of the heat from the light emitting layer 13 into the phase transfer material layer 40, but also heat radiation from the phase transfer material layer 40 to the glass substrate 11 and, accordingly, a long service life can further be attained.

### EXAMPLE 4

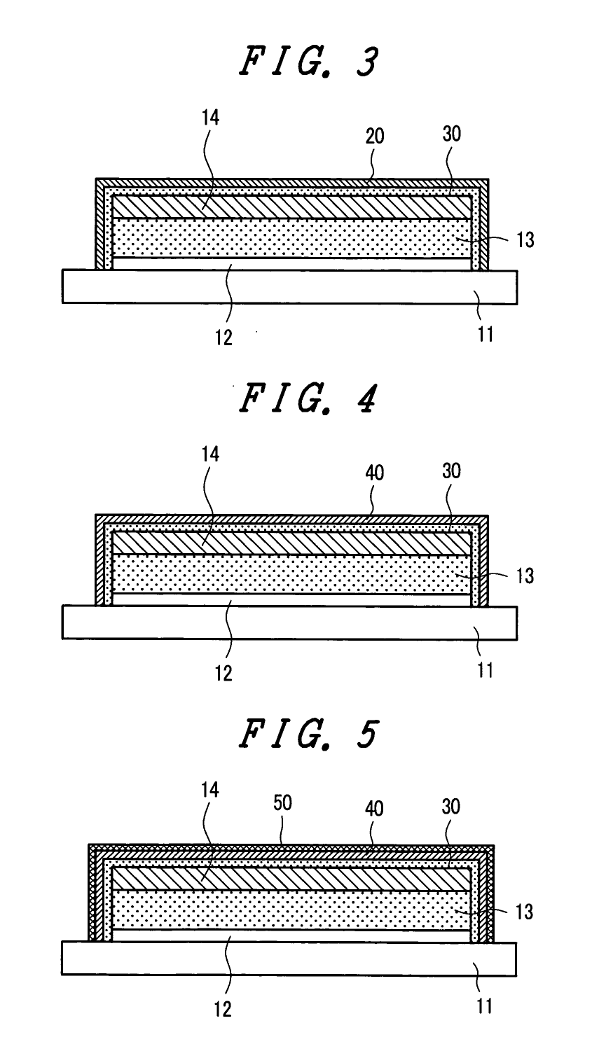

FIG. 5 is a cross-sectional diagram schematically showing a layer constitution of an organic EL element of Example 4 of an organic EL display device according to the invention. Further, explanations of same components as those in Examples 1 to 3 are omitted. In Example 4, a metallic film (of, for example, aluminum or nickel) 50 is further formed on the phase transfer material layer 40 as in Example 3. Other constitutions than the one described above is same as in FIG. 2. Further, the phase transfer material layer 20 as described in Example 1 or 2 can be used in place of the phase transfer material layer 40.

According to the organic EL display device constituted as in Example 4, in addition to the effects in Examples 1 to 3, the heat absorbed by the phase transfer material layer 40 can quickly be radiated to the glass substrate 11 and, accordingly, a long service life can further be attained.

Further, as for materials for the liquid crystalline polymer film to be used in each of the aforementioned Examples according to the invention, following material, for example, can be used singly or in mixtures of two types or more thereof:
a cholesteric liquid crystal;
cholesteryl acetate;
cholesteryl propionate;
cholesteryl nanoate;
cholesteryl oleyl carbonate;
cholesteryl nonanoate;
cholesteryl benzoate;
cholesteryl chloride; and
cholesteric oleyl carbonate.

Any one of these materials may be mixed with a high boiling point solvent.

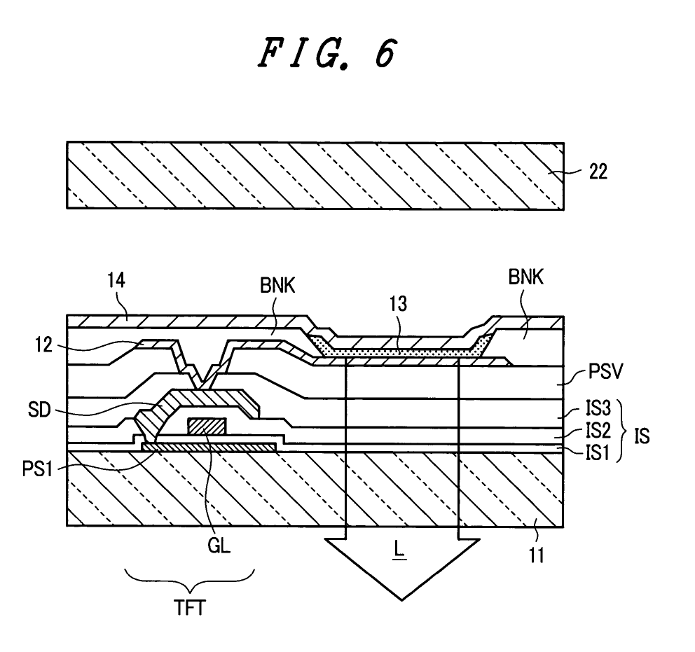

FIG. 6 is a cross-sectional diagram showing an example of constitution of a neighborhood of an organic EL element, namely, one pixel of an organic EL display device of a bottom emission type to which the invention is applied. The organic EL display device as shown in FIG. 6 is of an active matrix type which comprises a thin film transistor TFT on a major face of a glass substrate 11. A light emitting portion is constituted by sandwiching an organic light emitting layer 13 between an anode 12 which is one of electrodes to be driven by the aforementioned thin film transistor TFT and a cathode 14 which is the other electrode. Further, the thin film transistor TFT is constituted by a polysilicon semiconductor layer PSI, a gate insulating layer ISI, a gate line (gate electrode) GL, a source/drain electrode SD and an interlayer insulating layers IS2 and IS3.

The anode 12 which is a pixel electrode is constituted by a transparent conductive layer (ITO or the like) formed in a film state as an upper layer on a passivation layer PSV and is electrically in contact with a source/drain electrode SD of the thin film transistor TFT by a contact hole opened through the passivation layer PSV and the interlayer insulating layer IS3. Further, the organic light emitting layer 13 is formed by evaporation in a concave portion surrounded by a bank BNK which is constituted by an insulating layer applied on the anode 12 or formed by an application device such as an inkjet. Then, the cathode 14 is formed such that it covers the organic light emitting layer 13 and the bank BNK as a solid film.

In this organic EL display device as denoted as the bottom emission type, light L emitted from the light emitting layer is ejected from a surface of the glass substrate 11 to outside as shown by the arrow. Therefore, the cathode 14 is considered to have a light reflective ability. A sealing container 22 (sealing glass substrate) is bonded on the side of the major face of the glass substrate 11, to thereby seal an inside of a sealing performed around a peripheral portion (not shown) thereof in a vacuum state. The sealing of this sealing container 22 has been described in FIG. 2.

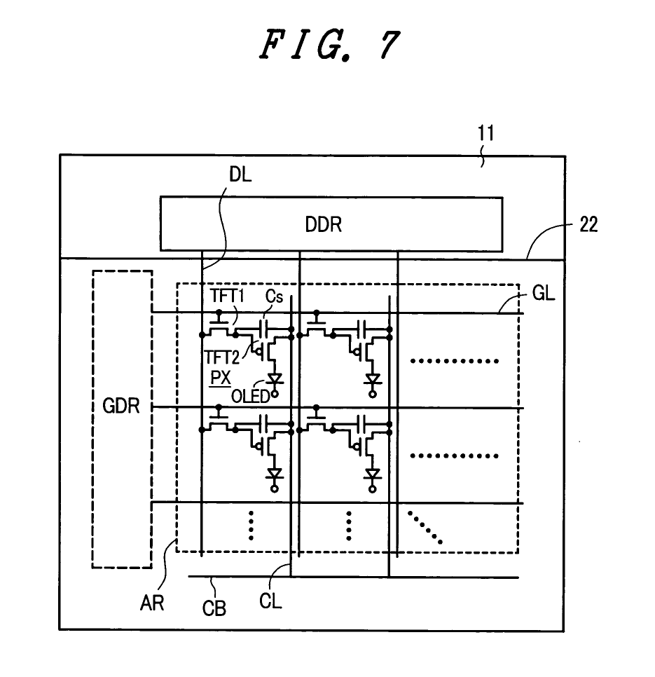

FIG. 7 is an equivalent circuit diagram showing an example of an entire constitution of an organic EL display device. Pixels PX constituting the organic EL element having a constitution as described in FIG. 6 is arrayed in a matrix state in a display region AR, to thereby constitute a two-dimensional display device. Each of the pixels PX is constituted by a first thin film transistor TFT 1, a second thin film transistor TFT 2, a capacitor Cs and an organic EL element OLED. The organic EL element OLED is constituted by the anode 12, the organic light emitting layer 13 and the cathode 14 as shown in FIG. 6. In the display region AR, a drain line DL and a gate line GL for supplying a driver signal to each pixel are arranged in a crossing state therebetween. A portion of the glass substrate 11, being larger in size than a glass substrate constituting the sealing container 22, is protruded from the sealing container 22. A drain driver DDR is mounted on such protruded portion and supplies a display signal to the drain line DL.

On the other hand, a gate driver GDR is directly formed on the glass substrate 11 covered by the sealing container 22 in a so-called system-on-glass form. This gate driver GDR is connected with the gate line GL. Further, a source line CL is arranged in the display region AR. This source line CL is connected with an exterior source by a terminal (not shown) via a source line bus line CB.

The gate line GL is connected with one (on this occasion, a drain electrode) of source/drain electrodes of a first thin film transistor TFT 1 constituting the pixel PX, while the drain line DL is connected with the other electrode (on this occasion, source electrode). The first thin film transistor TFT 1 is a switch for allowing the pixel PX to incorporate the display signal and, when it is turned on by being selected by means of the gate line GL, charges in accordance with the display signal to be supplied from the drain line DL are accumulated in the capacitor Cs. The second thin film transistor TFT 2 is turned on when the first thin film transistor TFT 1 is turned off and, then, supplies a current in accordance with a magnitude of the display signal accumulated in the capacitor Cs from the source line CL to the organic EL element OLED. The organic EL element OLED emits light in accordance with a volume of the current thus supplied.

As for methods for forming the organic EL element OLED constituting the pixel of this organic EL display device, there are various types of methods. Among them, there is a method in which an evaporation technique is utilized. This evaporation technique is performed such that an organic EL light emitting layer is deposited in a pixel region by using an evaporation mask having a hole per pixel.

The invention can be applied to the organic El display device in general and, particularly, by applying it to a large-screen organic EL display device for a television set, deterioration of characteristics to be caused by heat generated in the organic light emitting layer is suppressed and, accordingly, a long service life can be attained.

1. An organic EL display device, comprising:
a metallic wiring comprising a first electrode and a reference potential line formed on a major face of an insulating substrate;
at least one layer of a light emitting layer; and
a second electrode formed in a state of covering the organic light emitting layer,
the organic EL display device, further comprising:
a phase transfer material layer which is in contact with at least one of the first electrode and the second electrode and performs phase transfer with temperature changes.

2. The organic EL display device as set forth in claim 1, wherein a temperature at which the phase transfer material layer performs the phase transfer is in the range of from room temperature to a maximum allowable temperature of the organic EL light emitting layer.

3. The organic EL display device as set forth in claim 2, wherein the room temperature is in the range of from 20° C. to 25° C.

4. The organic EL display device as set forth in claim 2 or 3, wherein a maximum heat generating temperature of the organic EL light emitting layer is 50° C. which is a maximum value of a glass transition temperature thereof.

5. The organic EL display device as set forth in claim 2, wherein the maximum allowable temperature of the organic EL light emitting layer is a maximum heat generating temperature of the organic EL light emitting layer.

6. The organic EL display device as set forth in claim 5, wherein the maximum heat generating temperature of the organic EL light emitting layer is approximately 100° C.

7. The organic EL display device as set forth in claim 1, wherein the phase transfer material layer is connected with the metallic wiring formed on the major face of the insulating substrate.

8. The organic EL display device as set forth in claim 1, wherein the phase transfer material layer is connected with the insulating substrate.

9. The organic EL display device as set forth in claim 1, wherein the phase transfer material layer is formed by a liquid crystalline polymeric material.

10. The organic EL display device as set forth in claim 9, wherein the liquid crystalline polymeric material is represented by any one of the following chemical formulae (1) to (6) or any mixture thereof: 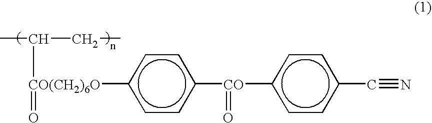
poly(6-{4-[(4-cyanophenoxy)carbonyl]phenoxy}hexylacrylate); 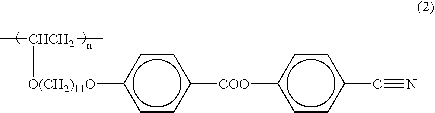
poly(1-{11-[4-(4-cyanophenoxycarbonyl)phenoxy]undecyloxy}ethylene); 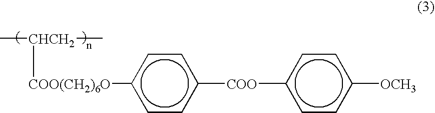
poly(1-{6-[4-(4-methoxyphenoxycarbonyl)phenoxy]hexyloxycarbonyl}ethylene); 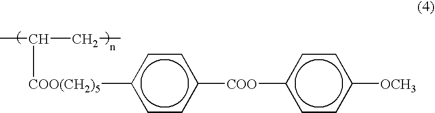
poly(1-{5-[4-(4-methoxyphenyloxycarbonyl)phenyloxy]pentyloxycarbonyl}ethylene); 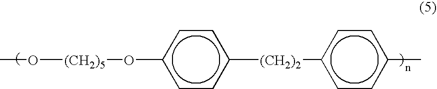
poly[oxypentane-1,5-diyloxy(3-methyl-1,4-phenylene)ethylene-1,4-phenylene]; 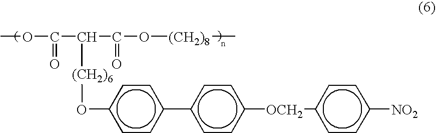
poly(oxy-2-{6-[4′-(4-nitrophenyl)methyloxybiphenyl-4-yl]oxyhexyl}malonyloxyoctane-1,8-diyl).

11. An organic EL display device, comprising:
a metallic wiring comprising a first electrode and a reference potential line formed on a major face of an insulating substrate;
an organic light emitting layer; and
a second electrode,
wherein at least one layer of the organic light emitting layer is arranged between the first electrode and the second electrode,
the organic EL display device further comprising:
a phase transfer material layer which is disposed on a side of the organic light emitting layer and performs phase transfer with temperature changes.

12. The organic EL display device as set forth in claim 11, wherein a temperature at which the phase transfer material layer performs the phase transfer is in the range of from room temperature to a maximum allowable temperature of the organic EL light emitting layer.

13. The organic EL display device as set forth in claim 12, wherein the room temperature is in the range of from 20° C. to 25° C.

14. The organic EL display device as set forth in claim 12 or 13, wherein a maximum heat generating temperature of the organic EL light emitting layer is 50° C. which is a maximum value of a glass transition temperature thereof.

15. The organic EL display device as set forth in claim 12, wherein the maximum allowable temperature of the organic EL light emitting layer is a maximum heat generating temperature of the organic EL light emitting layer.

16. The organic EL display device as set forth in claim 15, wherein the maximum heat generating temperature of the organic EL light emitting layer is approximately 100° C.

17. The organic EL display device as set forth in claim 11, wherein the phase transfer material layer is connected with the metallic wiring formed on the major face of the insulating substrate.

18. The organic EL display device as set forth in claim 11, wherein the phase transfer material layer is connected with the insulating substrate.

19. The organic EL display device as set forth in claim 11, wherein the phase transfer material layer is formed by a liquid crystalline polymeric material.

20. The organic EL display device as set forth in claim 11, wherein the phase transfer material layer is in contact with a side face of the organic light emitting layer.
